(19) United States
(12) Patent Application Publication
(10) Pub. No.: US 2016/0146899 A1
(43) Pub. Date: May 26, 2016

(54) METHOD AND APPARATUS FOR MEASURING CAPACITY OF BATTERY

(71) Applicant: uPI Semiconductor Corp., Hsinchu County (TW)

(72) Inventors: Kuo-Liang Teng, Hsinchu County (TW); Jih-Liang Juang, Hsinchu County (TW)

(21) Appl. No.: 14/741,462

(22) Filed: Jun. 17, 2015

(30) Foreign Application Priority Data
Nov. 20, 2014 (TW) 103140245

(51) Int. Cl. G01R 31/36

(52) U.S. Cl. CPC G01R 31/3682; G01R 31/3675; G01R 31/3651

(57) ABSTRACT

A method and an apparatus for measuring a capacity of a battery are provided. The apparatus comprises a battery status measuring module, a coulometer, and a calculating module. The battery status measuring module is used for monitoring a battery status of a battery. The coulometer is used for measuring an output quantity of electricity of the battery to obtain a coulometer capacity. The calculating module is coupled to the battery status measuring module and the coulometer to receive the battery status and the coulometer capacity. The calculating module looks into a lookup table according to the battery status to obtain a measuring a capacity of the battery, dynamically determines a weight value according to the battery status, and adjusts the measuring capacity of the battery and the coulometer capacity to calculate a displaying capacity of the battery.

### CROSS-REFERENCE TO RELATED APPLICATION

This application claims the priority benefit of Taiwan application serial no. 103140245, filed on Nov. 20, 2014. The entirety of the above-mentioned patent application is hereby incorporated by reference herein and made a part of this specification.

### BACKGROUND

1. Field of the Invention

The invention is directed to battery measurement and more particularly, to a method and apparatus for measuring capacity.

2. Description of Related Art

Along with development of technologies and convenience brought thereby, electronic apparatuses (e.g., mobile phones, tablet computers, notebook computers and so on) have gradually become essential to people's lives or work or life. In addition, with technical progress of various devices (e.g., processors, screens, communication devices, cameras and so on) of the electronic apparatuses, manufacturers have to enhance capacities or reduce power consumption of batteries for the electronic apparatuses, so as to increase endurance of the electronic apparatuses. A displaying battery capacity value is an important indicator for a sure to evaluate performance or use degree of the electronic apparatus.

Generally, a battery capacity (e.g., a displaying capacity value) of the electronic apparatus is estimated by using a voltage lookup table. FIG. 1 is a graph showing a relationship between a voltage and a capacity of a battery. In this case, the battery capacity may be represented by using a state of charge (SOC) (i.e., the horizontal axis illustrated in FIG. 1), of which the unit is %. The vertical axis of FIG. 1 represents the battery voltage, of which the unit is volt (V). With reference to FIG. 1, when the battery capacity is estimated by using the voltage lookup table on a voltage flat area of the battery (e.g., with the SOC between 30% and 80%), a minor voltage measurement error will lead to a severe error in the displaying capacity of the battery. Moreover, along with a discharging state of the battery, the estimation of the battery capacity will result in a dramatic oscillation phenomenon appearing in graph showing the relationship between the voltage and the SOC.

### SUMMARY

The invention provides a method and an apparatus for measuring a capacity of a battery capable of improving accuracy of reporting the capacity of the battery.

According to an aspect, the invention is directed to a method for measuring a capacity of a battery. The method includes: searching in at least one lookup table according to a battery status of the battery to obtain a capacity estimation value of the battery; measuring an output quantity of electricity of the batter by a coulometer to obtain a coulometer capacity; dynamically determining a weight value according to the battery status; and adjusting the capacity estimation value of the battery and the coulometer capacity according to the weight value to calculate a displaying capacity of the battery.

According to another aspect, the invention is directed to an apparatus for measuring a capacity of a battery. The apparatus includes a battery status measuring module, a coulometer and a calculating module. The battery status measuring module is configured to monitor a battery status of the battery. The coulometer is configured to measure an output quantity of electricity of the battery to obtain a coulometer capacity. The calculating module is coupled with the battery status measuring module and the coulometer to receive the battery status and the coulometer capacity. The calculating module searches in at least one lookup table according to the battery status of the battery to obtain a capacity estimation value of the battery, dynamically determines a weight value according to the battery status, and adjusts the capacity estimation value of the battery and the coulometer capacity according to the weight value to calculate the displaying capacity of the battery.

To sum up, in the method and the apparatus for measuring the capacity of the battery of the invention may, the weight value can be dynamically determined according to the battery status of the battery, and the capacity estimation value of the battery and the coulometer capacity can be adjusted according to the weight value, so as to improve the accuracy of the displaying capacity of the battery.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a graph showing a relationship between a voltage and a capacity of a battery.

FIG. 2 is a schematic block diagram illustrating a capacity measuring apparatus of a battery according to an embodiment of the invention.

FIG. 3 is a flowchart illustrating a method for measuring a capacity of a battery according to an embodiment of the invention.

FIG. 4 illustrates an example flowchart of estimating the capacity of the battery.

FIG. 5 illustrates an example of a pseudo code estimating the capacity of the battery.

FIG. 6A and FIG. 6B are simulation graphs illustrating the displaying capacity of the battery according to an embodiment of the invention.

FIG. 7A and FIG. 7B are simulation graphs illustrating the displaying capacity of the battery according to an embodiment of the invention.

### DESCRIPTION OF EMBODIMENTS

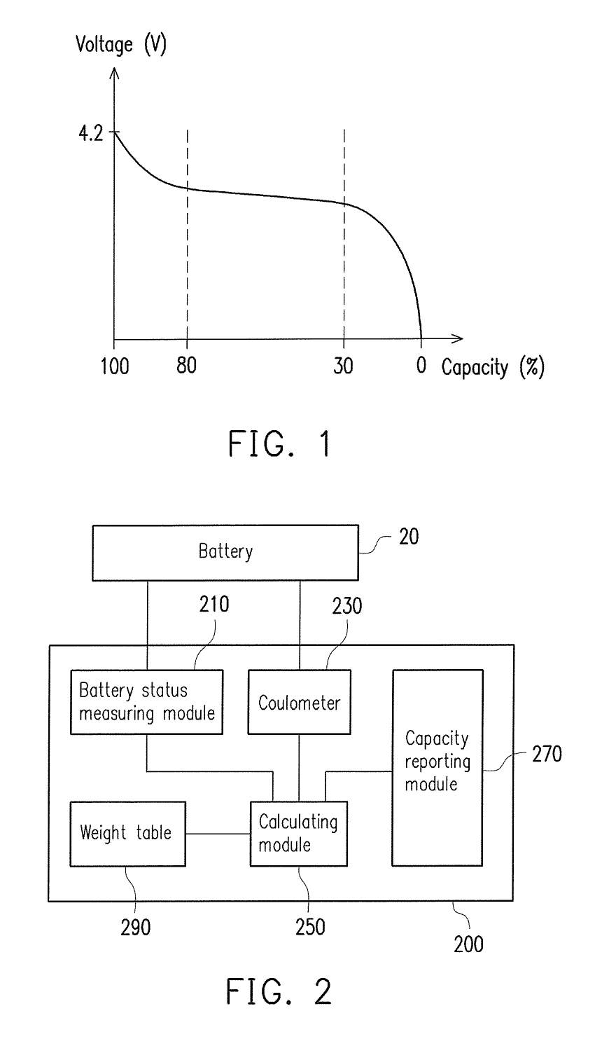

FIG. 2 is a schematic block diagram illustrating a capacity measuring apparatus 200 of a battery according to an embodiment of the invention. With reference to FIG. 2, the capacity measuring apparatus 200 includes a battery status measuring module 210, a coulometer 230, a calculating module 250, a capacity reporting module 270 and a weight table 290.

According to different design requirements, the battery status measuring module 210 may include a battery voltage measuring module, a temperature measuring module, current measuring module and/or any other battery status sensing/measuring circuit. The battery status measuring module 210 is configured to monitor a battery status of a battery 20. Therein, the battery status includes one of a voltage value, a current value and a temperature value or a combination thereof. The temperature value includes an ambient temperature value and/or a temperature value of the battery 20. The coulometer 230 may be, for example, a coulomb counter obtaining coulometer capacity of the battery 20 by means of an integration operation on a current flowing in/out from the battery. For example, the coulometer 230 may be configured to measure an output quantity of electricity (discharge quantity) of the battery 20 to obtain the coulometer capacity.

The calculating module 250 is coupled with the battery status measuring module 210 and the coulometer 230 to receive the battery status and the coulometer capacity. The calculating module 250 may include a central processing unit (or a central processor), microprocessor, a micro-controller, a chip set (e.g., a southbridge chip) and/or other operating circuits. Firmware and/or software may run in the calculating module 250. The firmware may be a basic input/output system (BIOS). The software may be an operating system (OS), a driver, an application and/or software.

According to different design requirements, the capacity reporting module 270 may be a device, such as a screen, a speaker, a light emitting diode (LED) presenting a displaying capacity of the battery by means of a video, an image, a text, a sound or brightness. In some other embodiments, the capacity measuring apparatus 200 may also transmit a digital or an analog signal (with respect to the displaying capacity of the battery) to a processing circuit or an external electronic apparatus of the next stage by means of the capacity reporting module 270. The weight table 290 may be stored in a storage unit (e.g., a memory, and a hard disc drive) of the capacity measuring apparatus 200 and record a relationship among the voltage value, the coulometer weight value and the lookup-table weight value. In some embodiments, the storage unit storing the weight table 290 may be embedded in a memory, a cache or a register of the calculating module 250. In some other embodiments, the storage unit storing the weight table 290 may also be disposed in a memory outside the calculating module 250. According to different design requirements, the storage unit of the weight table 290 may be a dynamic random access memory (DRAM), a static random access memory (SRAM), a volatile memory or a non-volatile memory (NVM).

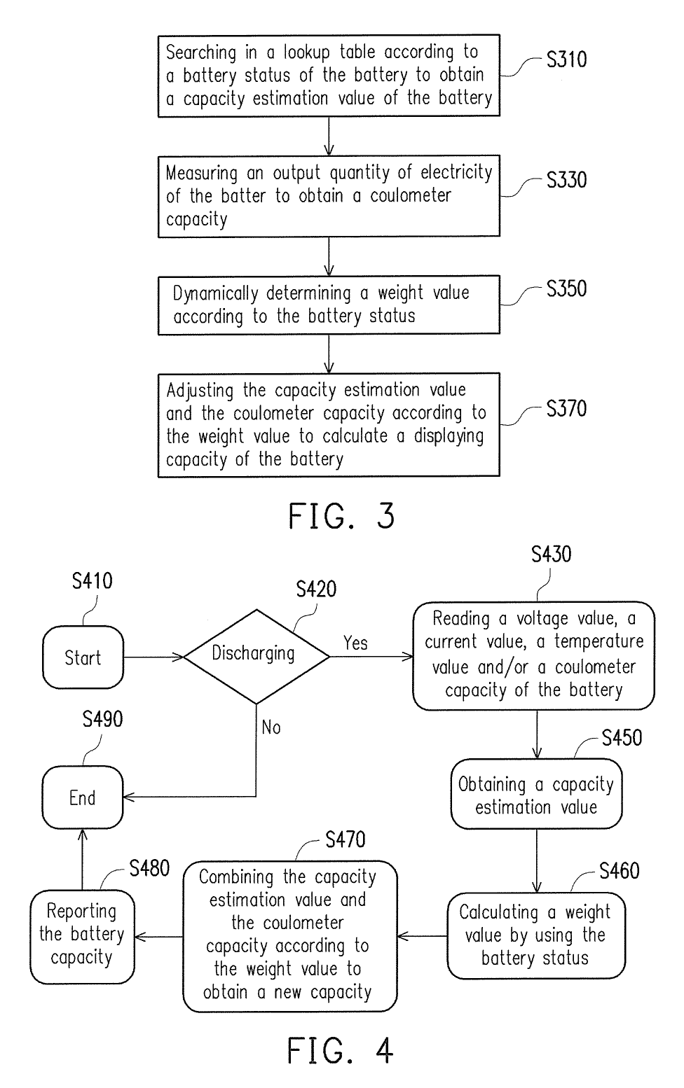

FIG. 3 is a flowchart illustrating a method for measuring according to an embodiment of the invention. With reference to FIG. 3, the method for measuring the capacity of the battery may be adaptive for the capacity measuring apparatus 200 of FIG. 2. In the following context, the method for measuring the capacity of the battery of the present embodiment will be described with reference to each device or module in the capacity measuring apparatus 200. Each step of the method may be adjusted according to actual implementation situation, and the invention is not limited thereto.

In step S310, the calculating module 250 searches in the lookup table according to the battery status of the battery 20 to obtain the capacity estimation value of the battery. Specifically, the capacity measuring apparatus 200 may be connected with the battery 20 under measurement and obtain the battery status containing one of a voltage value, a current value and the temperature value or a combination thereof by means of the battery status measuring module 210. The calculating module 250 compares the obtained battery status with the lookup table, in which the lookup table is stored in, for example, a storage unit inside the capacity measuring apparatus 200. The lookup table records a relationship between one of the voltage value, the current value and the temperature value or a combination thereof and the capacity estimation value of the battery, such that the calculating module 250 may obtain the capacity estimation value of the battery according to the comparison result. In other embodiments, operation details with respect to “the calculating module 250 searching in the lookup table according to the battery status of the battery 20” may refer to the conventional voltage-capacity lookup table, by which a voltage of the battery 20 is transferred into the capacity estimation value of the battery of the battery 20.

It should be noted that in an embodiment, before step S310, the calculating module 250 may also determine whether the battery 20 is in a charging state according to the current value of the battery 20 obtained by the battery status measuring module 210. If determining that the battery 20 is in the charging state, the calculating module 250 does not perform step S310. Otherwise, if determining that the battery 20 is not in the charging state (e.g., in a discharging state), the calculating module 250 continues to perform step S310.

In step S330, the coulometer 230 measures the output quantity of electricity of the battery 20 to obtain the coulometer capacity. In some embodiments, details with respect to the coulometer 230 obtaining the coulometer capacity may be derived with reference to the description related to the coulometer 230 illustrated in FIG. 2 and thus, will not be repeated. In other embodiments, operation detailed with respect to “the coulometer 230 measuring the output quantity of electricity of the battery 20” may refer to the operations related to the conventional technique of “the measurement of the battery using a coulometer”. In the embodiment illustrated in FIG. 3, step S330 is performed after step S310. In some other embodiments, it may also be step S330 performed before step S310. In yet some other embodiments, step S310 and step S330 may be simultaneously performed.

In step S350, the calculating module 250 dynamically determines a weight value according to the battery status. In the present embodiment, when a change of the voltage value, the current value or the temperature value occurs, the calculating module 250 adjusts the weight value according to the voltage value, the current value or the temperature value. In the embodiment illustrated in FIG. 3, step S350 is performed after step S330. In some other embodiments, it may also be step S350 performed before step S330. In yet some other embodiments, step S350 and step S330 may be simultaneously performed.

In an embodiment, the calculating module 250 may dynamically measure the temperature value (e.g., the temperature value of the battery 20 or the ambient temperature value) by means of the battery status measuring module 210. The calculating module 250 may also dynamically measure the voltage value of the battery 20 by means of the battery status measuring module 210. According to a change of the temperature value, the calculating module 250 may dynamically select a corresponding weight table from a plurality of weight tables. The calculating module 250 searches in the weight table according to the voltage value of the battery 20 to obtain the weight value. In the present embodiment, the weight table records a relationship among the voltage value, the coulometer weight value and the lookup-table weight value. When the voltage value is smaller, the coulometer weight value is decreased, or the lookup-table weight value is increased. The weight value includes the coulometer weight value and the lookup-table weight value.

For example, Table (1) to Table (3) are weight tables corresponding to different temperature values. Taking Table (1) for illustration, Table (1) is a corresponding weight table in which the temperature value measured by the battery status measuring module 210 is smaller than 15° C. In Table (1), the coulometer weight value is decreased as the voltage value is smaller, and the lookup-table weight value is increased as the voltage value is smaller. Table (2) and Table (3) may be derived in the same way and will not be repeated hereinafter. In an application example, when the temperature value (i.e., the temperature value of the battery 20 or the ambient temperature value) measured by the battery status measuring module 210 is 25° C., the calculating module 250 selects Table (2) as the corresponding weight table according to the change of the temperature value. If it is assumed that the voltage value of the battery 20 measured by the battery status measuring module 210 is 4000 mV, the calculating module 250 adjusts the coulometer weight value as 60% thereof, and adjusts the lookup-table weight value as 40% thereof

TABLE (1)
<15° C.

| Voltage value | Coulometer weight value | Lookup-table weight value |
|---|---|---|
| (mV) | (%) | (%) |
| >4300 | 100 | 0 |
| 4300~4100 | 90 | 10 |
| 4100~3900 | 70 | 30 |
| 3900~3700 | 30 | 70 |
| 3700~3500 | 10 | 90 |
| <3500 | 0 | 100 |

TABLE (2)
15° C. to 45° C.

| Voltage value | Coulometer weight value | Lookup-table weight value |
|---|---|---|
| (mV) | (%) | (%) |
| >4300 | 100 | 0 |
| 4300~4100 | 80 | 20 |
| 4100~3900 | 60 | 40 |
| 3900~3700 | 40 | 60 |
| 3700~3500 | 20 | 80 |
| <3500 | 0 | 100 |

TABLE (3)
>45° C.

| Voltage value | Coulometer weight value | Lookup-table weight value |
|---|---|---|
| (mV) | (%) | (%) |
| >4300 | 100 | 0 |
| 4300~4100 | 90 | 10 |
| 4100~3900 | 70 | 30 |
| 3900~3700 | 30 | 70 |
| 3700~3500 | 10 | 90 |
| <3500 | 0 | 100 |

It should be noted that persons applying the present embodiment may adjust the relationship among the voltage value, the coulometer weight value and the lookup-table weight value in each weight table according to design requirements. The coulometer weight value may be increased as the voltage value is smaller, and the lookup-table weight value may also be decreased as the voltage value is smaller. In some other embodiments, one of the coulometer weight value and the lookup-table weight value is not changed with the voltage value (e.g., maintained in a constant value, such as 50% or 60%)), and the other one is changed with the voltage value. In the examples of implementation illustrated in Table (1) to Table (3), a sum of the coulometer weight value and the lookup-table weight value is 100%; however, other embodiments may not be limited thereto. For example, in other embodiments, the sum of the coulometer weight value and the lookup-table weight value may also be a certain percentage, such as 80%, 120% or 150%, which is not limited in the invention.

In some other embodiments, when the capacity estimation value of the battery is greater than a threshold, the calculating module 250 may maintain the weight value, but when the change of the voltage value indicates that the capacity estimation value of the battery is smaller than the threshold (e.g., 10% or 20%), the calculating module 250 adjusts the weight value. The weight value includes the coulometer weight value and the lookup-table weight value. When the change of the voltage value indicates that the capacity estimation value of the battery is smaller than the threshold (e.g., 10% or 20%), the calculating module 250 may increase the lookup-table weight value as the capacity estimation value of the battery becomes smaller, and/or decrease the coulometer weight value as the capacity estimation value of the battery becomes smaller. When the change of the voltage value indicates that the capacity estimation value of the battery is greater than the threshold, the calculating module 250 may set the lookup-table weight value to be a static proportion value (e.g., 0, 20% or 40%). For example, when the change of the voltage value indicates that the capacity estimation value of the battery is greater than 30%, the calculating module 250 sets the lookup-table weight value as a constant value, 30% and sets the coulometer weight value as a constant value, 80%. When the change of the voltage value indicates that the capacity estimation value of the battery is 20% (which is smaller than 30%), the calculating module 250 sets the lookup-table weight value as 50% and sets the coulometer weight value as 50%. When the change of the voltage value indicates that the capacity estimation value of the battery is 10% (which is smaller than 30%), the calculating module 250 sets the lookup-table weight value as 70% and sets the coulometer weight value as 30%.

In step S370, the calculating module 250 adjusts the capacity estimation value of the battery and coulometer capacity according to the weight value to calculate a displaying capacity of the battery of the battery 20. In an embodiment, the calculating module 250 calculates a first product of the capacity estimation value of the battery multiplying the lookup-table weight value, a second product of the coulometer capacity multiplying the coulometer weight value and a sum of the first product and the second product to obtain the displaying capacity of the battery. For example, if it is assumed that the capacity estimation value of the battery is 80%, the lookup-table weight value is 30%, the coulometer capacity is 75%, the coulometer weight value is 70%. After the calculation by the calculating module 250, the first product is calculated as 80%*30%=24%, the second product is calculated as 75%*70%=52.5%, and the displaying capacity of the battery is calculated as 80%*30%+75%*70%=76.5%. Then, the calculating module 250 may report the displaying capacity of the battery by means of the capacity reporting module 270.

FIG. 4 illustrates an example flowchart of estimating the capacity of the battery. With reference to FIG. 4, the calculating module 250 starts the process of estimating the capacity of the battery 20 (step S410) and determines whether the battery 20 is in a discharging state (step S420). If the battery is not in the discharging state, the calculating module 250 ends the process of estimating the capacity of the battery 20 (step S490). Otherwise, if the battery 20 is in the discharging state, in step S430, the calculating module 250 reads a battery status (e.g., a voltage value, a current value and/or a temperature value) of the battery 20 by means of the battery status measuring module 210 and obtains a coulometer capacity of the battery 20 during the discharging process by means of the coulometer 230. Details with respect to step S430 may refer to the description related to step S330 of FIG. 3.

In step S450, the calculating module 250 obtains a capacity estimation value of the battery according to the battery status (e.g., the voltage value, the current value and/or the temperature value). Details with respect to step S450 may refer to the description related to step S310 of FIG. 3. In step S460, the calculating module 250 calculates a weight value by using the battery status (e.g., the voltage value, the current value and/or the temperature value). Details with respect to step S460 may refer to the description related to step S350 of FIG. 3. In step S470, the calculating module 250 may obtain a displaying capacity of the battery by combining/mixing the capacity estimation value of the battery and the coulometer capacity according to the calculated weight value. Details with respect to step S470 may refer to the description related to step S370 of FIG. 3. Then, the calculating module 250 reports the displaying capacity of the battery by means of the capacity reporting module 270 (step S480) and ends the capacity estimation process (step S490).

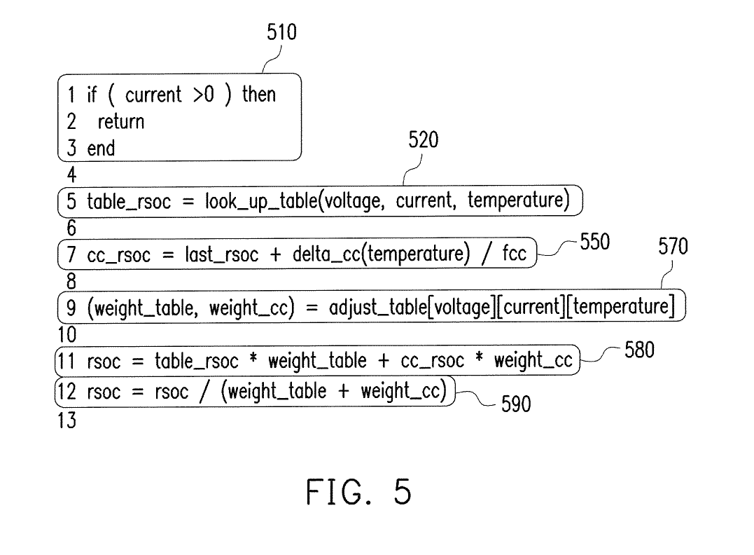

Moreover, the method for measuring the battery capacity of the invention may be implemented in a foam of program code which is stored in the storage unit of the capacity measuring apparatus 200 and loaded by the calculating module 250 to execute the method for measuring the battery capacity. For example, FIG. 5 illustrates an example of a pseudo code estimating the capacity of the battery. With reference to FIG. 5, in Code 510, whether the battery is in a charging state is determined, where “current” indicates a current value of a battery status. If being in the charging state, the battery exits the code function. In Code 520, the battery status is compared with a lookup table, where “voltage” refers to a voltage value of the battery status, and “temperature” refers to a temperature value. After the voltage value, the current value and the temperature value are input to the lookup table function (i.e., lookup_table), a capacity estimation value of the battery (i.e., table_rsoc) is obtained. In Code 550, a coulometer capacity (i.e., cc_rsoc) is estimated according to a capacity measured by the coulometer and the battery capacity that is previously reported, such as the previous coulometer capacity or the previous displaying capacity of the battery, (i.e., last_rsoc). Therein, the temperature value is input to a coulometer temperature compensation function (i.e., delta_cc), in which “fcc” represents the total capacity of the battery. In Code 570, the voltage value represented by “voltage”, the current value represented by “current” and the temperature value represented by “temperature” of the battery status are compared in a three-dimensional weight table (i.e., adjust_table[voltage][current][temperature]), to obtain a coulometer weight value (i.e. weight_cc) and a lookup-table weight value (i.e., weight_table). In Code 580, a displaying capacity of the battery (i.e., rsoc) is calculated according to the coulometer weight value, the lookup-table weight value, the coulometer capacity and the capacity estimation value of the battery, in Code 590, the displaying capacity of the battery calculated in Code 580 is divided by a sum of the coulometer weight value and the lookup-table weight value to obtain a final displaying capacity of the battery.

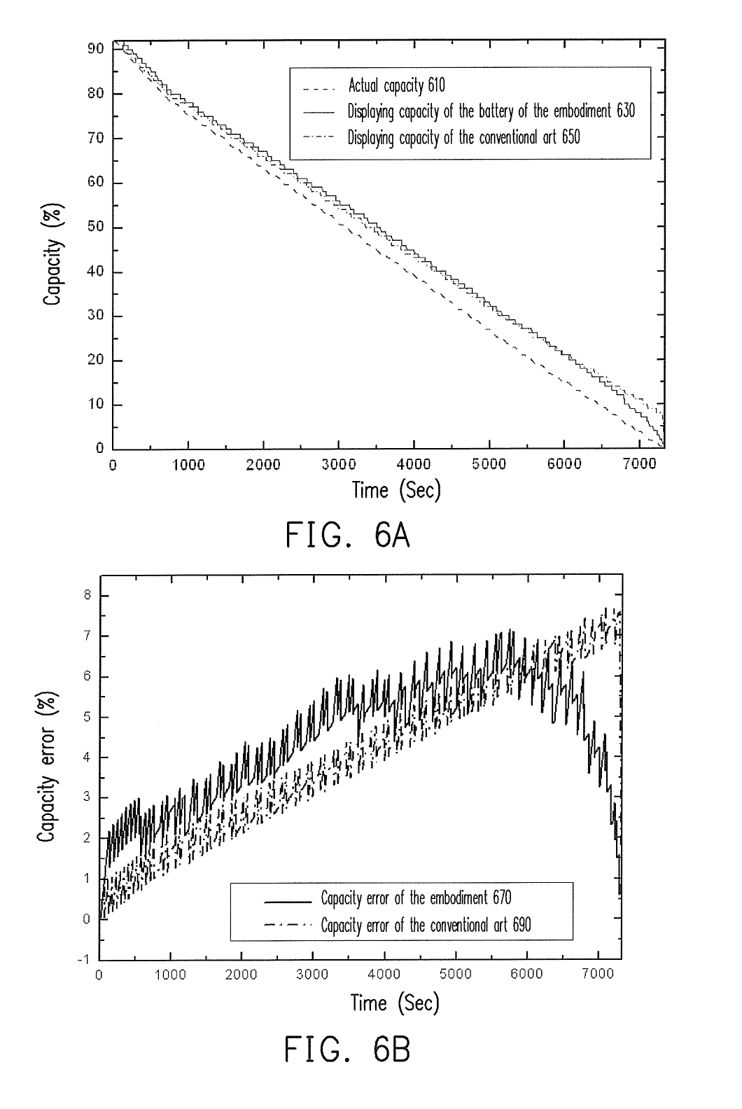

FIG. 6A and FIG. 6B are simulation graphs illustrating the displaying capacity of the battery according to an embodiment of the invention. When the change of the voltage value indicates that the capacity estimation value of the battery is greater than 20%, the calculating module 250 sets the lookup-table weight value as 0, and thus, the displaying capacity of the battery is fully represented by the second product. If the coulometer weight value is 100%, the calculating module 250 fully calculates the coulometer capacity as the displaying capacity of the battery. Following the capacity estimation value of the battery being smaller than 20%, the calculating module 250 gradually increases the lookup-table weight value. With reference to FIG. 6A, a displaying capacity 630 of the battery in this example gradually approaches an actual capacity 610 after being lower than 20%. Then, with reference to FIG. 6B, in this example, a difference between the displaying capacity 630 of the battery and the actual capacity 610 is also gradually decreased. In the comparison with the conventional displaying capacity 650, the displaying capacity 630 of the battery estimated in the embodiments of the invention is closer to the actual capacity 610.

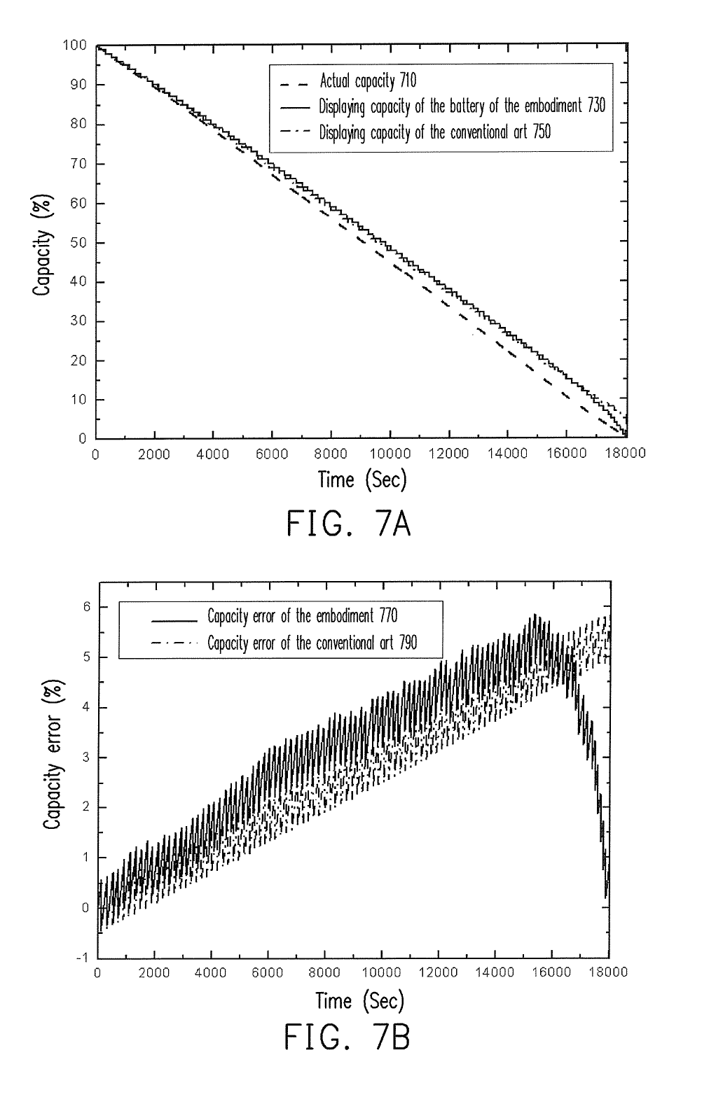

FIG. 7A and FIG. 7B are simulation graphs illustrating the displaying capacity of the battery according to an embodiment of the invention. In the comparison with the conventional displaying capacity 750, the displaying capacity 730 of the battery estimated in the embodiments of the invention is closer to the actual capacity 710. The example illustrated in FIG. 7A and FIG. 7B is different from the example illustrated FIG. 6A and FIG. 6B that in this example, when the change of the voltage value indicates that the capacity estimation value of the battery is greater than 10%, the calculating module 250 sets the lookup-table weight value as 0 and thus, fully serves the second product as the displaying capacity of the battery or fully calculates the coulometer capacity as the displaying capacity of the battery. Following the capacity estimation value of the battery being smaller than 10%, the calculating module 250 gradually increases the lookup-table weight value. With reference to FIG. 7A, in this example, a displaying capacity 730 of the battery gradually approaches the actual capacity 710 after being lower than 10%. Then, with reference to FIG. 7B, a difference between the displaying capacity 730 of the battery and the actual capacity 710 is also gradually decreased.

In light of the foregoing, the calculating module of the invention dynamically adjusts the weight value according to one or a combination of the voltage value, the current value and the temperature value of the battery status to adjust the capacity estimation value of the battery and the coulometer capacity to obtain the displaying capacity of the battery. Thereby, the severe capacity difference occurring to the voltage flat area of the battery in the voltage lookup table method, so as to improve the accuracy of estimating the battery capacity.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method for measuring a capacity of a battery, comprising:
searching in at least one lookup table according to a battery status of the battery to obtain a capacity estimation value of the battery;
measuring an output quantity of electricity of the batter by a coulometer to obtain a coulometer capacity;
dynamically determining a weight value according to the battery status; and
adjusting the capacity estimation value of the battery and the coulometer capacity according to the weight value to calculate a displaying capacity of the battery.

2. The method according to claim 1, wherein the battery status comprises one of a voltage value, a current value and a temperature value, or comprises a combination of the voltage value, the current value and the temperature value, and the step of dynamically determining the weight value according to the battery status comprises:
when a change of the voltage value, the current value or the temperature value occurs, adjusting the weight value according to the change of the voltage value, the current value or the temperature value.

3. The method according to claim 2, wherein the step of adjusting the weight value according to the change of the voltage value, the current value or the temperature value comprises:
dynamically selecting a corresponding weight table from a plurality of weight tables according to the change of the temperature value; and
searching in the corresponding weight table according to the voltage value of the battery to obtain the weight value.

4. The method according to claim 3, wherein the corresponding weight table records a relationship among the voltage value, a coulometer weight value and a lookup-table weight value, and when the voltage value is smaller, the coulometer weight value is decreased, or the lookup-table weight value is increased.

5. The method according to claim 3, wherein the weight value comprises a coulometer weight value and a lookup-table weight value, and the step of adjusting the weight value according to the change of the voltage value, the current value or the temperature value comprises:
when the capacity estimation value of the battery is smaller than a threshold, adjusting the weight value to increase the lookup-table weight value as the capacity estimation value of the battery becomes smaller, or to decrease the coulometer weight value as the capacity estimation value of the battery becomes smaller.

6. The method according to claim 5, wherein the step of adjusting the weight value according to the change of the voltage value, the current value or the temperature value comprises:
when the capacity estimation value of the battery is greater than the threshold, setting the lookup-table weight value as a proportion value.

7. The method according to claim 3, wherein the weight value comprises a coulometer weight value and a lookup-table weight value, and the step of adjusting the capacity estimation value of the battery and the coulometer capacity according to the weight value to calculate the displaying capacity of the battery comprises:
calculating a first product of the capacity estimation value of the battery multiplying the lookup-table weight value;
calculating a second product of the coulometer capacity multiplying the coulometer weight value; and
calculating a sum of the first product and the second product to obtain the displaying capacity of the battery.

8. The method according to claim 2, wherein the temperature value comprises an ambient temperature value or a temperature value of the battery.

9. The method according to claim 2, wherein the step of searching in the lookup table according to the battery status of the battery to obtain the capacity estimation value of the battery comprises:
determining whether the battery is in a charging state according to the current value.

10. An apparatus for measuring a capacity of a battery, comprising:
a battery status measuring module, configured to monitor a battery status of the battery;
a coulometer, configured to measure an output quantity of electricity of the battery to obtain a coulometer capacity;
a calculating module, coupled with the battery status measuring module and the coulometer to receive the battery status and the coulometer capacity, wherein the calculating module searches in at least one lookup table according to the battery status of the battery to obtain a capacity estimation value of the battery, dynamically determines a weight value according to the battery status, and adjusts the capacity estimation value of the battery and the coulometer capacity according to the weight value to calculate a displaying capacity of the battery.

11. The apparatus according to claim 10, wherein the battery status comprises one of a voltage value, a current value and a temperature value or a combination thereof, and when a change of the voltage value, the current value or the temperature value occurs, the calculating module adjusts the weight value according to the change of the voltage value, the current value or the temperature value.

12. The apparatus according to claim 11, wherein the calculating module dynamically selects a corresponding weight table from a plurality of weight tables according to the change of the temperature value and searches in the corresponding weight table according to the voltage value of the battery to obtain the weight value.

13. The apparatus according to claim 12, wherein the corresponding weight table records a relationship among the voltage value, a coulometer weight value and a lookup-table weight value, and when the voltage value is smaller, the coulometer weight value is decreased, or the lookup-table weight value is increased.

14. The apparatus according to claim 12, wherein the weight value comprises a coulometer weight value and a lookup-table weight value, when the change of the voltage value indicates that the capacity estimation value of the battery is smaller than a threshold, the calculating module adjusts the weight value to increase the lookup-table weight value as the capacity estimation value of the battery becomes smaller, or to decrease the coulometer weight value as the capacity estimation value of the battery becomes smaller.

15. The apparatus according to claim 14, wherein when the change of the voltage value indicates that the capacity estimation value of the battery is greater than the threshold, the calculating module sets the lookup-table weight value as a proportion value.

16. The apparatus according to claim 12, wherein the weight value comprises a coulometer weight value and a lookup-table weight value, the calculating module calculates a first product of the capacity estimation value of the battery multiplying the lookup-table weight value, calculates a second product of the coulometer capacity multiplying the coulometer weight value, and calculates a sum of the first product and the second product to obtain the displaying capacity of the battery.

17. The apparatus according to claim 11, wherein the temperature value comprises an ambient temperature value or a temperature value of the battery.

18. The apparatus according to claim 11, wherein the calculating module determines whether the battery is in a charging state according to the current value.
